(19) United States
(12) Patent Application Publication
(10) Pub. No.: US 2008/0179610 A1
(43) Pub. Date: Jul. 31, 2008

(54) SEMICONDUCTOR LIGHT EMISSION DEVICE EMITTING POLARIZED LIGHT AND METHOD FOR MANUFACTURING THE SAME

(75) Inventors: Kuniyoshi OKAMOTO, Kyoto (JP); Satoshi Nakagawa, Kyoto (JP); Hiroki Tujimura, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/876,642

(22) Filed: Oct. 22, 2007

(30) Foreign Application Priority Data
Oct. 23, 2006 (JP) 2006-287541
Jul. 11, 2007 (JP) 2007-182218

(51) Int. Cl. H01L 33/00; H01L 21/00

(52) U.S. Cl. 257/98; 438/29; 257/E21.001; 257/E33.001

(57) ABSTRACT

A semiconductor light emission device including: a nitride semiconductor stack having an active layer capable of emitting light, a growth surface of the nitride semiconductor stack being a substantially nonpolar plane or substantially semipolar plane; and a reflection section formed in a surface of the device opposite to a light extraction surface through which the light emitted from the active layer is extracted, the reflection section reflecting the light to the light extraction surface.

### CROSS REFERENCE TO RELATED APPLICATIONS AND INCORPORATION BY REFERENCE

This application is based upon and claims the benefit of priority from prior Japanese Patent Application No. 2006-287541, filed on Oct. 23, 2006, and prior Japanese Patent Application No. 2007-182218, filed on Jul. 11, 2007, the entire contents of which are incorporated by reference herein.

### BACKGROUND OF THE INVENTION

1. Field of the Invention

The present invention relates to a semiconductor light emission device having a nitride semiconductor stack.

2. Description of the Related Art

Japanese Patent Laid-open Publication No. 9-219562 (Patent Literature 1) discloses a semiconductor light emission device (a semiconductor laser) including a nitride semiconductor stack having a plurality of GaN or AlGaN layers stacked on a sapphire substrate. This semiconductor light emission device includes a reflection layer in the top or bottom. The reflection layer is composed of a multilayer film including a plurality of insulating layers stacked.

In the case of applying the above-described technique of Patent Literature 1 to a light emission diode, the reflection layer composed of the aforementioned insulating multilayer film is provided for a surface opposite to a light extraction surface through which light emitted from an active layer is extracted. Light traveling in a direction opposite to a light extraction direction among the light emitted from the active layer can be therefore reflected toward the light extraction surface. Accordingly, it is possible to extract through the light extraction surface also light which escaped through the surface opposite to the light extraction surface, thus increasing an amount of light extracted through the light extraction surface.

In the aforementioned light emission diode, the reflection layer is provided to increase the amount of light extracted through the light extraction surface. However, light emitted from the active layer is not polarized, and the polarization ratio of extracted light is low.

### SUMMARY OF THE INVENTION

A semiconductor light emission device according to the present invention includes: a nitride semiconductor stack including an active layer capable of emitting light, a growth surface of the nitride semiconductor stack being a substantially nonpolar plane or substantially semipolar plane; and a reflection section formed in a surface of the device opposite to a light extraction surface through which the light emitted from the active layer is extracted, the reflection section reflecting the light to the light extraction surface.

A method for manufacturing a semiconductor light emission device according to the present invention includes: a step of forming a nitride semiconductor stack which includes an active layer capable of emitting light, a growth surface of the nitride semiconductor stack being a substantially nonpolar plane or substantially semipolar plane; and a step of forming a reflection section in a surface of the device opposite to a light extraction surface through which the light emitted from the active layer is extracted, the reflection section reflecting the light to the light extraction surface.

Herein, the substantially nonpolar plane is an idea including a nonpolar plane and a plane having an off angle within ±1 degree from the orientation of the nonpolar plane. The substantially semipolar plane is an idea including a semipolar plane and a plane having an off angle within ±1 degree from the orientation of the semipolar plane.

According to the present invention, the nitride semiconductor stack whose growth surface is a substantially nonpolar plane or a substantially semipolar plane is provided, so that the active layer is allowed to emit polarized light. It is therefore possible to increase the polarization ratio of light extracted. Light traveling in the opposite direction to the light extraction surface among the emitted light is generally dispersed by an external casing or the like, resulting in reduction in polarization ratio of light. In the present invention, the light traveling in the opposite direction to the light extraction surface can be reflected by the reflection layer toward the light extraction surface. Accordingly, the reduction in polarization ratio due to external dispersion of light radiated at the side opposite to the light extraction surface can be reduced. It is therefore possible to increase the amount of light extracted through the light extraction surface while increasing the polarization ratio.

### BRIEF DESCRIPTION OF DRAWINGS

FIG. 1 is a cross-sectional view of a semiconductor light emission device according to a first embodiment.

FIG. 2 is a cross-sectional view of a semiconductor light emission device according to a second embodiment.

FIG. 3 is a cross-sectional view of a semiconductor light emission device according to a third embodiment.

FIG. 4 is a cross-sectional view of the semiconductor light emission device according to the third embodiment at a step of a manufacturing process.

FIG. 5 is a cross-sectional view of the semiconductor light emission device according to the third embodiment at another step of the manufacturing process.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

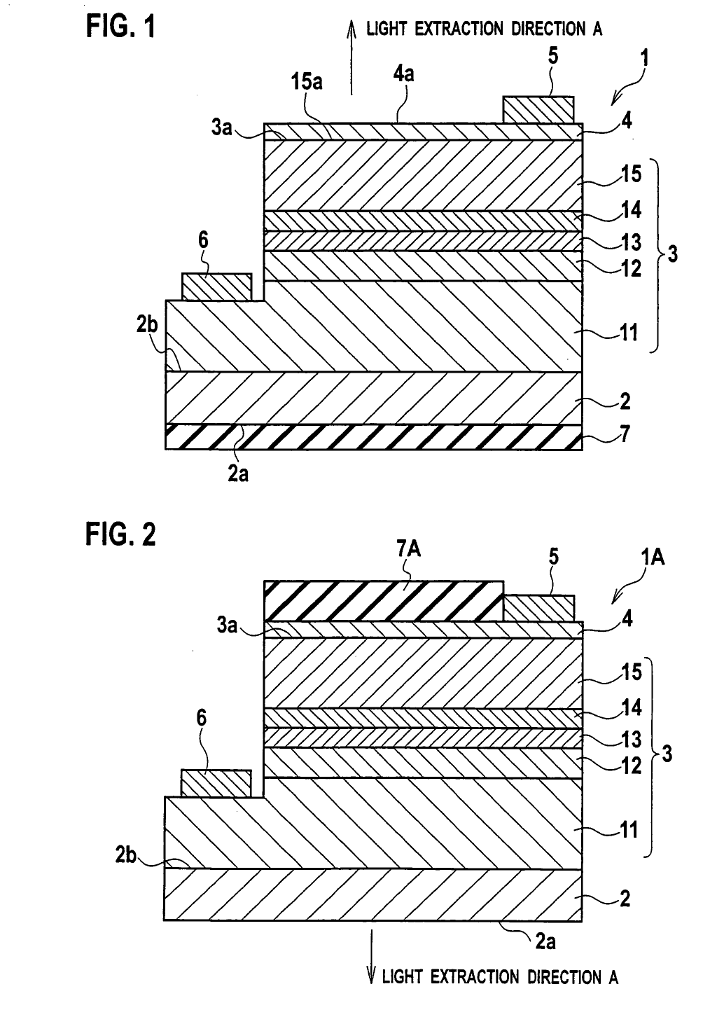

With reference to the drawings, a description is given of a first embodiment of a light emitting diode (LED) to which the present invention is applied. FIG. 1 is a cross-sectional view of a semiconductor light emission device (LED) according to the first embodiment.

As shown in FIG. 1, a semiconductor light emission device 1 includes a substrate 2, a nitride semiconductor stack 3 provided on the substrate 2, an anode electrode 4, a cathode electrode 6, and a reflection layer 7.

The substrate 2 is composed of single-crystal gallium nitride (GaN). The method for manufacturing single-crystal gallium nitride is not particularly limited. On a growth surface 2b of the substrate 2, the nitride semiconductor stack 3 is placed. The growth surface 2b is composed of nonpolar m-plane. When the GaN crystalline structure is approximated by a hexagonal crystal of a hexagonal cylinder, m-plane is a surface corresponding to a side surface of the hexagonal cylinder ((10-10) plane, for example). A surface of the substrate 2 opposite to a light extraction direction A, a bottom surface 2a, on which the reflection layer 7 is formed, is mirror-finished so that height of roughness thereof is smaller than wavelength of light emitted from a later-described active layer 12.

The nitride semiconductor stack 3 includes an n-type contact layer 11, the active layer 12, a final barrier layer 13, a p-type electron blocking layer 14, and a p-type contact layer 15 sequentially stacked from the substrate 2 side. As described above, the growth surface 2b of the substrate 2 is composed of m-plane. Accordingly, the growth surface 3a of the nitride semiconductor stack 3 provided on the growth surface 2b of the substrate 2 is also composed of nonpolar m-plane which allows the active layer 12 to emit polarized light.

The n-type contact layer 11 is an about 3 μm or more thick n-type GaN layer doped with silicon having a concentration of about 1×10¹⁸ cm⁻³ as an n-type dopant.

The active layer 12 has a quantum well structure in which five In_{z}Ga_{1-z}N layers doped with silicon (about 3 nm thick) and five GaN layers (about 9 nm thick) are alternately stacked. The active layer 12 emits blue light (wavelength: about 430 nm, for example). Herein, Z, which is a ratio of In to Ga in the In_{z}Ga_{1-z}N layer, satisfies 0.05<=Z<=0.2. To cause the active layer 12 to emit green light, Z is set to 0.2<=Z.

The final barrier layer 13 is composed of an about 40 nm thick GaN layer. As for doping, p-type doping, n-type doping, or non-doping may be employed, but non-doping is preferred.

The p-type electron blocking layer 14 is composed of an about 28 nm thick AlGaN layer doped with magnesium having a concentration of about 3×10¹⁹ cm⁻³ as a p-type dopant.

The p-type contact layer 15 is an about 70 nm thick GaN layer doped with magnesium having a concentration of about 1×10²⁰ cm⁻³ as a p-type dopant. A light extraction side surface 15a of the p-type contact layer 15 facing the light extraction direction A is provided to extract from the nitride semiconductor stack 3 light emitted from the active layer 12. The light extraction side surface 15a is mirror-finished so that roughness thereof is not more than 100 nm in order to reduce dispersion of light and prevent reduction in polarization ratio. For example, such a flat mirror surface as described above can be obtained by crystal growth. The optical extraction side surface 15a is the same as the growth surface 3a of the nitride semiconductor stack 3.

The anode electrode 4 is a metallic layer including Ni and Au layers sequentially stacked from the p-type contact layer 15 side. The anode electrode 4 is ohmic-connected to the p-type contact layer 15 and formed so as to cover substantially the entire surface of the p-type contact layer 15 so that current passes through the nitride semiconductor stack 3 uniformly in the horizontal direction (the direction orthogonal to the stacking direction). The anode electrode 4 has a thickness of not more than about 200 Å so as to transmit light emitted from the active layer 12. The light extraction surface 4a of the anode electrode 4 is provided to extract light emitted from the active layer 12 and is mirror-finished so that roughness thereof is not more than 100 nm similarly to the light extraction side surface 15a of the p-type contact layer 15. Such a mirror surface as described above can be obtained using electron beam evaporation. As described above, light emitted from the active layer 12 can be prevented by the mirror-finished light extraction side surface 15a and light extraction surface 4a from dispersing and accordingly extracted with a high polarization ratio maintained. On a part of the anode electrode 4, a connecting section 5 including Ti and Au layers stacked is provided.

The cathode electrode 6 includes a Ti layer and an Al layer stacked. The cathode electrode 6 is formed in an exposed region of the upper surface of the n-type contact layer 11 and ohmic-connected thereto.

The reflection layer 7 is provided to reflect to the light extraction direction A light traveling in the opposite direction to the light extraction direction A and is formed on the bottom surface 2a of the substrate 2, which is opposite to the light extraction surface 4a. The reflection layer 7 has a stacking structure in which a plurality of insulating SiO₂ layers and a plurality of insulating Si_{X}N_{Y} layers (X and Y are positive integers) are alternately stacked. The materials of the reflection layer 7 are not limited to SiO₂ and Si_{X}N_{Y} films and may be properly selected from insulating films of SiON, ZrO₂, Al₂O₃, Nb₂O₃, TiO₂, and the like.

A thickness d of a pair of the SiO₂ and Si_{X}N_{Y} layers is set as shown in the following equation (1) so that reflected light rays interfere with each other to be intensified.

d=(λ/4n₁)+(λ/4n₂) (1)

Herein, λ is wavelength of light emitted from the active layer 12, and n₁ and n₂ are refractive indices of SiO₂ and Si_{X}N_{Y} layers, respectively.

Next, a description is given of an operation of the aforementioned semiconductor light emission device 1. In this light emission device 1, holes are supplied from the anode electrode 4 while electrons are supplied from the cathode electrode 6. The electrons are injected through the n-type contact layer 11 to the active layer 12, and the holes are injected through the semiconductor layers 13 to 15 into the active layer 12. The electrons and holes injected to the active layer 12 are combined with each other to emit light with a wavelength of about 430 nm. Herein, the light emitted from the active layer 12 is polarized since the growth surface 3a of the nitride semiconductor stack 3 is nonpolar m-plane.

Light traveling in the light extraction direction A among the polarized light is transmitted through the semiconductor layers 13 to 15 and anode electrode 4 to be extracted to the outside. On the other hand, light traveling in the opposite direction to the light extraction direction A is reflected on the reflection layer 7 in the light extraction direction A. Herein, since the bottom surface 2a of the substrate 2, on which the reflection layer 7 is formed, is mirror-finished, light dispersion at the bottom surface 2a can be reduced. Accordingly, the reduction in polarization ratio can be reduced. The light traveling toward the substrate 2 can be transmitted through the semiconductor layers 13 to 15 and anode electrode 4 to be extracted while not being dispersed and substantially being kept polarized.

Next, a description is given of a method for manufacturing the aforementioned semiconductor light emission device.

First, the substrate 2 which is composed of single crystal GaN and has the growth surface 2b being nonpolar m-plane is prepared. Herein, the substrate 2 with the growth surface 2b being nonpolar m-plane is produced as follows: first cutting a piece out of a single crystal GaN substrate whose growth surface is C-plane; and then polishing the surface of the cut piece by chemical mechanical polishing (CMP) for mirror finishing so that orientation errors related to both orientations (0001) and (11-20) are within ±1 degree, preferably ±0.3 degrees. In the thus-obtained substrate 2 with the growth surface 2b being m-plane, there are a few crystal defects such as dislocations or stacking faults, and roughness of the surface thereof can be reduced to the atomic level.

Next, the nitride semiconductor stack 3 is grown on the above-described substrate 2 by MOCVD. Specifically, first, the substrate 2 is put in a processing chamber of an MOCVD apparatus (not shown) and placed on a susceptor capable of heating and rotating. The processing chamber is set to 1/10 to 1 atm, and the atmosphere of the processing chamber is always exhausted.

Next, to grow a GaN layer while controlling roughness of the surface thereof, ammonium gas is supplied with carrier gas (H₂ gas) to the processing chamber in which the substrate 2 is held while the temperature of the processing chamber is increased to about 1000 to 1100° C.

Next, after the temperature of the substrate 2 is increased to about 1000 to 1100° C., ammonium, trimethylgallium, and silane are supplied to the processing chamber with carrier gas to grow the n-type contact layer 11 composed of an n-type GaN layer doped with silicon.

Next, the temperature of the substrate 2 is set to about 700 to 800° C., and then ammonium and trimethylgallium are supplied to the processing chamber with carrier gas to grow a non-doped GaN layer. Subsequently, silane and trimethylindium are supplied together with the above gas to grow an InGaN layer doped with silicon.

These steps of growing the non-doped GaN layer and doped InGaN layer are alternately repeated a predetermined number of times to form the active layer 12 having a quantum well structure. Thereafter, ammonium and trimethylgallium are supplied to the processing chamber with carrier gas to grow the final barrier layer 13 composed of a GaN layer.

Next, the temperature of the substrate 2 is increased to about 1000 to 1100° C., and then ammonium, trimethylgallium, trimethylaluminum, and ethylcyclopentadienylmagnesium are supplied with carrier gas to grow the p-type electron blocking layer 14 composed of a p-type AlGaN layer doped with magnesium.

Next, ammonium, trimethylgallium, and ethylcyclopentadienylmagnesium are supplied to the processing chamber with carrier gas while the temperature of the substrate 2 is maintained at about 1000 to 1100° C., thus growing the p-type contact layer 15 composed of a GaN layer doped with magnesium. The nitride semiconductor stack 3 with the growth surface 3a being nonpolar m-plane is thus completed.

Next, the substrate 2 with the nitride semiconductor stack 3 formed thereon is moved to a processing chamber capable of performing plasma CVD. A predetermined number of pairs of alternating SiO₂ and Si_{X}N_{Y} layers are grown so that the thickness of a pair of SiO₂ and Si_{X}N_{Y} layers satisfies Equation (1) to form the reflection layer 7 on the bottom surface 2a of the substrate 2.

Next, the anode electrode 4 is formed by a metal evaporator using resistance heating or electron beam evaporation. Thereafter, the substrate 2 with the nitride semiconductor stack 3 and reflection layer 7 formed thereon is moved to an etching chamber, and the nitride semiconductor stack 3 is partially plasma-etched so that a part of the n-type contact layer 11 is exposed.

Next, the connection section 5 and cathode electrode 6 are formed by a metal evaporator using resistance heating or electron beam evaporation. Thereafter, the obtained product is cleaved into each device. The semiconductor light emission device 1 shown in FIG. 1 is thus completed.

As described above, the semiconductor light emission device 1 according to the first embodiment includes the nitride semiconductor stack 3 with the growth surface 3a being nonpolar m-plane, and polarized light is emitted from the active layer 12. Light traveling in the opposite direction to the light extraction direction A among the emitted light is generally radiated through the bottom surface of the substrate and then dispersed by an external casing or the like, resulting in reduction in polarization ratio of the light. However, in the semiconductor light emission device 1 according to the first embodiment, the reflection layer 7 is provided on the bottom surface 2a of the substrate 2, so that light traveling in the opposite direction to the light extraction direction A can be reflected in the light extraction direction A. Accordingly, it is possible to prevent reduction in polarization ratio due to external dispersion of light radiated through the bottom surface 2a of the substrate 2.

Accordingly, the amount of light extracted through the light extraction surface 4a can be increased, and the polarization ratio of the light extracted through the light extraction surface 4a can be increased. Furthermore, mirror finishing of the bottom surface 2a of the substrate 2 can reduce dispersion of light at the bottom surface 2a when the light is incident from the substrate 2 to the reflection layer 7. The polarization ratio of the extracted light can be therefore increased.

As described above, the semiconductor light emission device 1 can provide light with a high polarization ratio. In the case of applying the semiconductor light emission device 1 to a light source of a liquid crystal display, therefore, one of polarization filters to polarize light can be omitted. Alternatively, an amount of light transmitted through the polarization filters can be increased.

Moreover, the reflection layer 7 is composed of SiO₂ and Si_{X}N_{Y}, so that the reflection layer 7 can be easily formed.

Still moreover, the reflection layer 7 is formed so that the thickness of a pair of SiO₂ and Si_{X}N_{Y} layers satisfies the equation (1). Accordingly, light beams reflected on interfaces between adjacent pairs of the SiO₂ and Si_{X}N_{Y} layers interfere with each other to increase the amount of light extracted.

### Second Embodiment

Next, a description is given of a second embodiment achieved by partially modifying the first embodiment. FIG. 2 is a cross-sectional view of a semiconductor light emission device according to the second embodiment. Components of the second embodiment same as those of the first embodiment are given same reference numerals, and the description thereof is omitted.

As shown in FIG. 2, in a semiconductor light emission device 1A, the light extraction direction A is a direction from the active layer 12 toward the substrate 2. In other words, light emitted from the active layer 12 is extracted through the bottom surface (light extraction surface) 2a of the substrate 2. In such a structure, a reflection layer 7A is formed on the upper surface of the anode electrode 4 which is on the opposite side to the bottom surface 2a of the substrate 2. The reflection layer 7A includes a stacking structure with SiO₂ and Si_{X}N_{Y} layers stacked similarly to the reflection layer 7 of the first embodiment.

By providing the reflection layer 7A on the upper surface of the anode electrode 4, it is possible to implement the semiconductor light emission device 1A in which light is extracted on the substrate 2 side.

### Third Embodiment

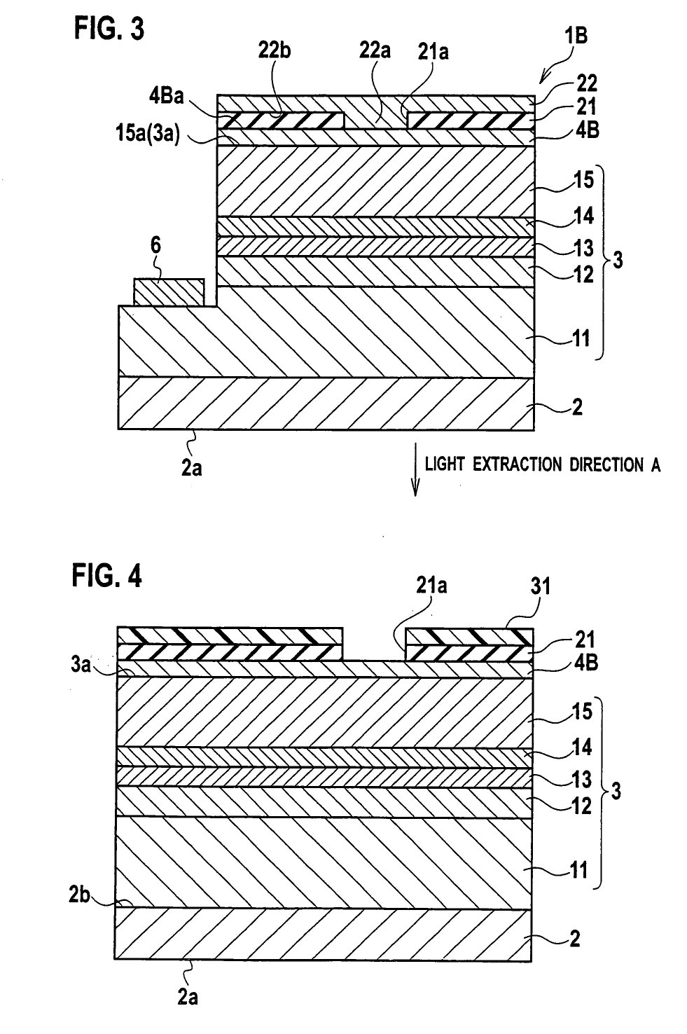

Next, a description is given of a third embodiment achieved by partially modifying the first embodiment. FIG. 3 is a cross-sectional view of a semiconductor light emission device according to the third embodiment. Components of the second embodiment same as those of the first embodiment are given same reference numerals, and the description thereof is omitted.

As shown in FIG. 3, a semiconductor light emission device 1B includes the substrate 2, the nitride semiconductor stack 3 provided on the substrate 2, an anode electrode (corresponding to a transparent electrode of claims) 4B, the cathode electrode 6, an insulating film 21, and an external electrode 22. The anode electrode 4B, insulating film 21, and external electrode 22 correspond to a reflection section of claims.

The anode electrode 4B is formed on the substantially entire upper surface 15a of the p-type contact layer 15, which is on the opposite side to the bottom surface (light extraction surface) 2a of the substrate 2. The anode electrode 4B has a thickness of about 200 to 300 nm and is a transparent electrode composed of ZnO. The transparent electrode herein is not like a general metallic electrode which is made thin (several tens nanometers, for example) to transmit light but is an electrode composed of a material which is capable of transmitting light even with a certain thickness (not less than several hundreds nanometers, for example).

The insulating film 21 is formed on an entire upper surface 4Ba of the anode electrode 4B. The insulating film 21 is provided to insulate a lower surface 22b of the external electrode 22 for light reflection. The insulating film 21 is composed of SiO₂ capable of transmitting light. Thickness of the insulating film 21 is not more than wavelength of light emitted from the active layer 12, preferably not more than “wavelength/a refraction index of the insulating film 21”. An example of the thickness of the insulating film 21 is about 50 nm. In a center part of the insulating film 21 including the center thereof, a part of the upper surface 4Ba of the anode electrode 4B is exposed to form an opening 21a for connection of the anode electrode 4B and external electrode 22.

The external electrode 22 is provided to electrically connect the anode electrode 4B and the outside and reflect in the light extraction direction A light traveling toward the anode electrode 4B. The external electrode 22 is formed on the upper surface of the insulating film 21. The external electrode 22 is made of a conductive material capable of reflecting light. Specifically, the external electrode 22 includes an Al layer (about 10 nm thick), a Ti layer (about 10 nm thick), and an Au layer (about 200 nm thick) sequentially stacked from the anode electrode 4B side. The external electrode 22 may include an Ag layer instead of the Al layer. The external electrode 22 includes a protrusion 22a formed in the opening 21a of the insulating film 21. The height of the protrusion 22a is equal to the thickness of the insulating film 21 which is not more than the wavelength of light emitted from the active layer 12. Accordingly, the polarization ratio of the light from the active layer 12 is prevented from being reduced by the protrusion 22a similar to a mirror-finished surface. The protrusion 22a of the external electrode 22 is ohmic-connected to the anode electrode 4B exposed in the opening 21a of the insulating film 21. On the other hand, the lower surface 22b of the external electrode 22 other than the protrusion 22a is insulated by the insulating film 21 and can reflect light without absorbing light.

Next, a description is given of an operation of the above described semiconductor light emission device 1. The description of the same operation as that of the semiconductor light emission device 1 of the first embodiment is simplified.

First, in the semiconductor light emission device 1B, polarized light is emitted from the active layer 12 when forward voltage is applied. Light traveling in the light extraction direction A among the emitted light is radiated to the outside through the rear face 2a of the substrate 2. On the other hand, light traveling toward the anode electrode 4B among the emitted light is transmitted through the anode electrode 4B and insulating film 21 and reaches the external electrode 22. The light is reflected on the lower surface 22b of the external electrode 22 in the light extraction direction A. The reflected light is radiated through the rear surface 2a of the substrate 2 to the outside.

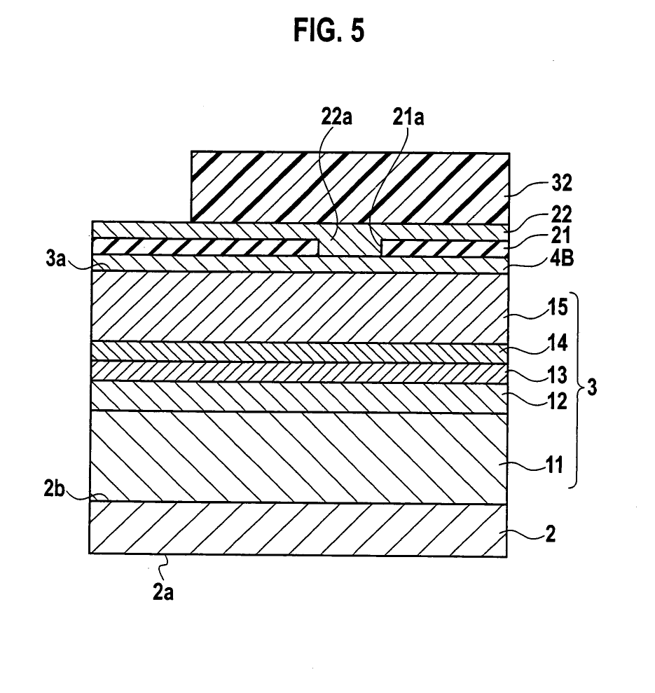

Next, a description is given of a method for manufacturing the above-described semiconductor light emission device 1B with reference to the drawings. FIGS. 4 and 5 are cross-sectional views in manufacturing steps of the semiconductor light emission device according to the third embodiment.

First, as shown in FIG. 4, similarly to the semiconductor light emission device 1 of the first embodiment, the nitride semiconductor stack 3 with the growth surface 3a being m-plane is epitaxially grown on the substrate 2 with the growth surface 2b being m-plane.

Next, the anode electrode 4B, which is composed of ZnO and electrically connected to the nitride semiconductor stack 3, is formed on the entire upper surface 15a of the p-type contact layer 15 by spattering or vacuum deposition.

Next, the insulating film 21 is formed on the entire upper surface 4Ba of the anode electrode 4B by plasma CVD. Thereafter, a resist film 31 having a desired pattern is formed, and the opening 21a is formed by etching. The resist film 31 is then removed.

Next, as shown in FIG. 5, the external electrode 22, which is made of a metallic multilayer film and electrically connected to the anode electrode 4B, is formed on the upper surface of the insulating film 21 and in the opening 21a. A resist film 32 is then formed.

Next, the layers 11 to 15, 4B, 21, and 22 are etched so that the n-type contact layer 11 is exposed as shown in FIG. 3. The cathode electrode 6 is then formed on the n-type contact layer 11. Eventually, the obtained product is divided into each device, thus completing the semiconductor light emission device 1B.

As described above, the semiconductor light emission device 1B includes the external electrode 22 capable of reflecting light. Accordingly, light traveling in the opposite direction to the light extraction direction A is reflected to travel in the light extraction direction A. This can increase an efficiency of extracting light. Moreover, the lower surface 22b of the external electrode 22 is insulated by the insulating film 21, so that light absorbed by the external electrode 22 can be reduced.

Moreover, the anode electrode 4B is composed of transparent ZnO, so that the anode electrode 4B can be made thick (about 200 to 300 nm thick). This allows current to spread horizontally across the anode electrode 4b even when wire is bonded to a part of the anode electrode 4B. Accordingly, light can be emitted from substantially the entire active layer 12, thus increasing the amount of light extracted to the outside. Furthermore, the anode electrode 4B is composed of transparent ZnO, so that abruption of light by the anode electrode 4B can be reduced.

### Other Embodiments

Hereinabove, the present invention is described in detail using the embodiments but is not limited to the embodiments described in this specification. The scope of the present invention is determined based on the scope of claims and equal scope thereto. In the following, a description is given of modifications of the aforementioned embodiments partially modified.

For example, the materials, thickness, and concentrations of the dopants of each layer can be properly changed.

The aforementioned embodiment is an example of the present invention applied to a light emission diode, but the present invention may be applied to another device such as a laser.

In the aforementioned embodiment, the growth surface 2b of the substrate 2 is m-plane. However, the growth surface of the substrate is not limited to m-plane and may be a substantially nonpolar plane or substantially semipolar plane capable of polarizing light emitted from the active layer. Herein, the substantially nonpolar plane is an idea including a nonpolar plane and a plane with an off angle within ±1 degree from the orientation of the nonpolar plane. The substantially semipolar plane is an idea including a semipolar plane and a plane having an off angle within ±1 degree from the orientation of the semipolar plane. Herein, a brief description is given of the crystalline structure and planes of GaN constituting the substrate. The crystalline structure of GaN is approximated by a hexagonal system of hexagonal cylinder type. The plane whose normal is the C axis along the axis of a hexagonal cylinder is C-plane (001). In the crystalline structure of GaN, as conventionally known, the polarization direction is equal to the direction of C-axis, and C-plane has different characteristics between the +C axis side and −C axis side. Accordingly, C-plane is a polar plane. On the other hand, each side surface of the hexagonal cylinder is m-plane (10-10), and a plane including a pair of ridges not adjacent to each other is a-plane (11-20). These crystalline planes are perpendicular to C-plane and orthogonal to the polarization direction. Accordingly, m-plane and a-plane are nonpolar. Moreover, the crystalline plane tilted at an angle other than 90 degrees diagonally intersects with the polarization direction and is therefore a semipolar plane having some polarity. Concrete examples of the semipolar plane are (10-1-1), (10-1-3), (11-22), (11-24), and (10-12) planes.

The material constituting the substrate is not limited to single crystal GaN and may be a sapphire substrate whose primary face is m-plane or a-plane, a spinel substrate whose primary face is (100) or (110) plane, a SiC substrate whose primary face is m-plane, a LiAlO₂ substrate, or the like.

In the aforementioned third embodiment, the anode electrode 4B is composed of ZnO but may be a different transparent electrode of ITO or IZO.

What is claimed is:

1. A semiconductor light emission device comprising:
a nitride semiconductor stack including an active layer capable of emitting light, a growth surface of the nitride semiconductor stack being a substantially nonpolar plane or substantially semipolar plane; and
a reflection section formed in a surface of the device opposite to a light extraction surface through which the light emitted from the active layer is extracted, the reflection section reflecting the light to the light extraction surface.

2. The semiconductor light emission device of claim 1, wherein
the reflection section includes a plurality of insulating films stacked.

3. The semiconductor light emission device of claim 2, wherein
the reflection section includes at least two stacked insulating films selected from SiO₂, SiN, SiON, ZrO₂, Al₂O₃, Nb₂O₃, and TiO₂ films.

4. The semiconductor light emission device of claim 3, wherein
the reflection section includes first and second insulating films alternately and repeatedly stacked, and
thickness of a pair of the first and second insulating films constituting the reflection section is (λ/4n₁)+(λ/4n₂) where λ is wavelength of light emitted from the active layer and n₁ and n₂ are refraction indices of the first and second insulating films, respectively.

5. The semiconductor light emission device of claim 1, wherein the reflection section comprises:
a transparent electrode electrically connected to the nitride semiconductor stack and is formed in a surface of the device opposite to the light extraction surface;
an insulating film which is formed on the transparent electrode and includes an opening to expose a part of the transparent electrode; and
an external electrode which is made of metal capable of reflecting light, formed on the insulating film, and electrically connected to the transparent electrode partially exposed in the opening of the insulating film.

6. The semiconductor light emission device of claim 1, wherein
the surface in which the reflection section is formed is a mirror-finished surface.

7. The semiconductor light emission device of claim 1, wherein
the nitride semiconductor stack has a hexagonal crystal structure; and
a growth surface of the nitride semiconductor stack is m-plane.

8. A method for manufacturing a semiconductor light emission device, the method comprising:
a step of forming a nitride semiconductor stack which includes an active layer capable of emitting light, a growth surface of the nitride semiconductor stack being a substantially nonpolar plane or substantially semipolar plane; and
a step of forming a reflection section in a surface of the device opposite to a light extraction surface through which the light emitted from the active layer is extracted, the reflection section reflecting the light to the light extraction surface.

9. The method of claim 8, wherein
the reflection section is formed by stacking a plurality of insulating films.

10. The method of claim 9, wherein
the reflection section is formed by stacking at least two insulating films selected from SiO₂, SiN, SiON, ZrO₂, Al₂O₃, Nb₂O₃, and TiO₂ films.

11. The method of claim 10, wherein
the reflection section is formed by alternately and repeatedly stacking first and second insulating films, and
thickness of a pair of the first and second insulating films constituting the reflection section is (λ/4n₁)+(λ/4n₂) where λ is wavelength of light emitted from the active layer and n₁ and n₂ are refraction indices of the first and second insulating films, respectively.

12. The method of claim 8, wherein the step of forming the reflection section comprises:
a step of forming a transparent electrode in a surface of the device opposite to the light extraction surface, the transparent electrode being electrically connected to the nitride semiconductor stack;
a step of forming an insulating film on the transparent electrode, the insulating film including an opening to expose a part of the transparent electrode; and
a step of forming an external electrode on the insulating film, the external electrode being made of metal capable of reflecting light and electrically connected to the transparent electrode partially exposed in the opening of the insulating film.

13. The method of claim 8, wherein
the surface in which the reflection section is formed is mirror-finished.

14. The method of claim 8, wherein
the nitride semiconductor stack is formed on a substrate having a hexagonal crystal structure whose growth surface is m-plane.
